(19) United States
(12) Patent Application Publication
(10) Pub. No.: US 2025/0294788 A1
(43) Pub. Date: Sep. 18, 2025

(54) PREPARATION METHOD FOR SEMICONDUCTOR DEVICE

(71) Applicant: Dynax Semiconductor, Inc., Suzhou (CN)

(72) Inventors: Hongtu QIAN, Suzhou (CN); Zili WU, Suzhou (CN); Xiao HAN, Suzhou (CN)

(73) Assignee: Dynax Semiconductor, Inc., Suzhou (CN)

(21) Appl. No.: 19/223,312

(22) Filed: May 30, 2025

Related U.S. Application Data
(63) Continuation of application No. PCT/CN2023/143554, filed on Dec. 29, 2023.

(30) Foreign Application Priority Data
Dec. 30, 2022 (CN) 202211734815.3

(51) Int. Cl. H10D 30/01; H01L 21/768; H10D 30/47; H10D 62/824; H10D 64/00; H10D 64/01

(52) U.S. Cl. CPC H10D 30/015; H01L 21/76877; H10D 64/01; H10D 30/475; H10D 62/824; H10D 64/111

(57) ABSTRACT

A preparation method for a semiconductor device includes: providing a substrate; preparing an epitaxial structure on a side of the substrate; preparing a gate electrode and gate connecting structure on a side, facing away from the substrate, of the epitaxial structure, where the gate connecting structure is electrically connected to at least part of the gate electrode. According to the present disclosure, by preparing a gate connecting structure that is electrically connected to at least part of the gate electrode, influence of resistance of the gate electrode may be reduced and a gain may be increased, so that leakage current is reduced.

### CROSS-REFERENCE TO RELATED APPLICATIONS

This application is a continuation of International Application No. PCT/CN2023/143554, filed on Dec. 29, 2023, which claims priority to Chinese Patent Application No. 202211734815.3, filed on Dec. 30, 2022. The disclosures of the aforementioned applications are hereby incorporated by reference in their entireties.

### TECHNICAL FIELD

The present disclosure relates to the field of semiconductor technologies, and in particular, to a preparation method for a semiconductor device.

### BACKGROUND

Gallium Nitride (GaN), as a semiconductor material, has significant advantages such as wide band gap, high electron saturation drift velocity, high breakdown field strength, and high temperature resistance. The GaN material is suitable for manufacturing high-temperature, high-voltage, high-frequency, and high-power electronic devices and has become a research hot spot in the semiconductor industry.

As for a GaN radio frequency (RF) power amplifier, it is required for an application circuit to achieve a balance between improvement in device power and gain characteristics, which is also a goal pursued by GaN RF chips. However, since power supply of a gate electrode is located on a single side of a device, the power supply for a gate on the other side is affected by resistance of the gate electrode, resulting in performance degradation.

### SUMMARY

The present disclosure provides a preparation method for a semiconductor device to reduce influence of resistance of a gate electrode and improve a gain while reducing leakage.

In a first aspect, the present disclosure provides a preparation method for a semiconductor device, including: providing substrate; preparing an epitaxial structure on a side of the substrate; preparing a gate electrode and a gate connecting structure on a side, facing away from the substrate, of the epitaxial structure, where the gate connecting structure is electrically connected to at least part of the gate electrode.

According to the preparation method for the semiconductor device provided by the present disclosure, by preparing a gate electrode and a gate connecting structure on a side, facing away from the substrate, of the epitaxial structure, the gate connecting structure is electrically connected to at least part of the gate electrode, which may reduce resistance of the gate electrode, improve gain of the gate electrode, and reduce leakage.

### BRIEF DESCRIPTION OF THE DRAWINGS

To more clearly illustrate technical solutions in embodiments of the present disclosure, accompanying drawings used in the description of the embodiments will be briefly introduced below. Obviously, the accompanying drawings in the following description are merely some embodiments of the present disclosure. For those skilled in the art, other accompanying drawings may be obtained from these accompanying drawings without creative effort.

FIG. 1 is a flowchart of a preparation method for a semiconductor device provided by an embodiment of the present disclosure.

FIG. 2 is a flowchart of a preparation method for a semiconductor device provided by another embodiment of the present disclosure.

FIG. 3 is a schematic structural diagram of a semiconductor device provided by an embodiment of the present disclosure.

FIG. 4 is a schematic structural diagram of a semiconductor device provided by another embodiment of the present disclosure.

FIG. 5 is a schematic structural diagram of a semiconductor device provided by still another embodiment of the present disclosure.

FIG. 6 is a flowchart of a preparation method of a semiconductor device provided by still another embodiment of the present disclosure.

FIG. 7 is a schematic structural diagram of a semiconductor device provided by yet still another embodiment of the present disclosure.

FIG. 8 is a cross-sectional view of the semiconductor device provided by FIG. 7 along section line A-A′.

FIG. 9 is a schematic flowchart of the preparation method of a semiconductor device provided by yet still another embodiment of the present disclosure.

FIG. 10 is a schematic structural diagram of a semiconductor device provided by yet still another embodiment of the present disclosure.

FIG. 11 is a cross-sectional view of the semiconductor device provided by FIG. 10 along section line B-B′.

FIG. 12 is a flowchart of a preparation method of a semiconductor device provided by yet still another embodiment of the present disclosure.

FIG. 13 is a schematic structural diagram of a semiconductor device provided by yet still another embodiment of the present disclosure.

FIG. 14 is a cross-sectional view of the semiconductor device provided by FIG. 13 along section line C-C′.

FIG. 15 is a flowchart of a preparation method of a semiconductor device provided by yet still another embodiment of the present disclosure.

FIG. 16 is another cross-sectional view of the semiconductor device provided by FIG. 13 along section line C-C′.

FIG. 17 is a schematic diagram of processes for preparing a semiconductor device provided by yet still another embodiment of the present disclosure.

### DETAILED DESCRIPTION OF THE EMBODIMENTS

Technical solutions in embodiments of the present disclosure will be described clearly and completely with reference to the accompanying drawings in the following. Obviously, the described embodiments are only part of the embodiments of the present disclosure, rather than all of them. Based on the embodiments of the present disclosure, all other embodiments obtained by those skilled in the art without creative effort shall fall within the scope of protection of the present disclosure.

In the description of the embodiments of the present disclosure, it should be understood that the terms “first” and “second” are used for descriptive purposes only and should not be construed as indicating or implying relative importance or implicitly specifying the quantity of the indicated technical features. Thus, features defined as “first” or “second” may explicitly or implicitly include one or more of the said features. In the description of the embodiments of the present disclosure, “a plurality” means two or more, unless otherwise specifically defined.

To enable those skilled in the art to implement and use the present disclosure, the following description is provided. Details are listed in the following description for explanatory purposes. It should be understood that those skilled in the art can recognize that the present disclosure can be implemented without these specific details. In other embodiments, well-known processes are not described in detail to avoid obscuring the description of the embodiments of the present disclosure with unnecessary details. Therefore, the present disclosure is not intended to be limited to the illustrated embodiments but is to be accorded the widest scope consistent with the principles and features disclosed in the embodiments of the present disclosure.

In the field of 5G communication, semiconductor RF devices require high bandwidth and high-frequency performance. Design and processing procedures of a gate structure are closely related to the frequency characteristics of the semiconductor device, directly affecting their operating frequency. Therefore, the design of the gate structure is particularly important in the design and preparation of the semiconductor device, playing a key role in the reliability and operational stability of the semiconductor device.

As for a GaN radio frequency (RF) power amplifiers, it is required for an application circuit to achieve a balance between improvement in device power and gain characteristics, which is also a goal pursued by GaN RF chips. Specifically, in a design of a traditional integrated circuit GaN RF chip, power supply of a gate electrode is located on a single side of a device, so that the power supply for a gate on the other side is reduced under an effect of the gate electrode, resulting in significant reduction in gain. Therefore, how to improve the gain of the semiconductor device while further enhancing their bandwidth and high-frequency performance, thereby achieving a performance balance in power amplifiers, has become an urgent problem to solve.

FIG. 1 is a flowchart of a preparation method for a semiconductor device provided by an embodiment of the present disclosure. As shown in FIG. 1, a preparation method for a semiconductor device includes the following steps.

S101: providing a substrate.

Exemplarily, material of the substrate may include one or a combination of sapphire, silicon carbide, silicon, gallium arsenide, gallium nitride, or aluminum nitride, and other materials suitable for growing gallium nitride. Preparation methods of the substrate may include: atmospheric pressure chemical vapor deposition, sub atmospheric pressure chemical vapor deposition, metal organic compound vapor deposition, low-pressure chemical vapor deposition, high-density plasma chemical vapor deposition, ultra-high vacuum chemical vapor deposition, plasma enhanced chemical vapor deposition, catalytic chemical vapor deposition, mixed physical chemical vapor deposition, rapid thermochemical vapor deposition, vapor phase epitaxy, pulsed laser deposition, atomic layer epitaxy, molecular beam epitaxy, sputtering or evaporation, and the like, which is not limited in the embodiment of the present disclosure.

S102: preparing an epitaxial structure on a side of the substrate.

Exemplarily, the epitaxial structure may be made of Group III-V nitrides including one or more of gallium nitride, aluminum gallium nitride, indium gallium nitride, aluminum nitride, and indium aluminum gallium nitride, and a two-dimensional electron gas can be formed in the epitaxial structure. Growth methods of the epitaxial structure may include metal organic chemical vapor deposition, hydride vapor phase epitaxy, molecular beam epitaxy, and liquid phase epitaxy, which are not limited in the embodiments of the present disclosure.

S103: preparing a gate electrode and a gate connecting structure on a side, facing away from the substrate, of the epitaxial structure, where the gate connecting structure is electrically connected to at least part of the gate electrode.

Exemplarily, the semiconductor device provided in the embodiments of the present disclosure may be a single cell structure or a multi-cell structure, which is not limited in the embodiments of the present disclosure. If the semiconductor device is the single cell structure, the semiconductor device may include a source-gate-drain basic structure. If the semiconductor device is a multi-cell structure, the semiconductor device may include a plurality of source-gate-drain basic structures. The gate electrode may extend in a first direction, and a plurality of gate electrodes may be arranged sequentially in a second direction. The first direction and the second direction may be in a same plane and the second direction may be perpendicular to the first direction.

Furthermore, the preparation method provided in the embodiments of the present disclosure may further include: preparing a gate connecting structure on the side, facing away from the substrate, of the epitaxial structure. The gate connecting structure is electrically connected to at least part of the gate electrode. Since charging and discharging speed of a junction capacitance may be affected by resistance of the gate electrode, which may further affect switching speed of the semiconductor device, the smaller the resistance of the gate electrode is, the faster the switching speed of the semiconductor device is. By electrically connecting the gate connecting structure to at least part of the gate electrode, the resistance of the gate electrode may be reduced, thereby improving the switching speed of the semiconductor device.

According to the preparation method of the semiconductor device provided in the embodiments of the present disclosure, the gate connecting structure is prepared on the side, facing away from the substrate, of the epitaxial structure, so that the gate connecting structure is electrically connected to at least part of the gate electrode, which may reduce an influence of the resistance of the gate electrode, improve a gain, and reduce leakage.

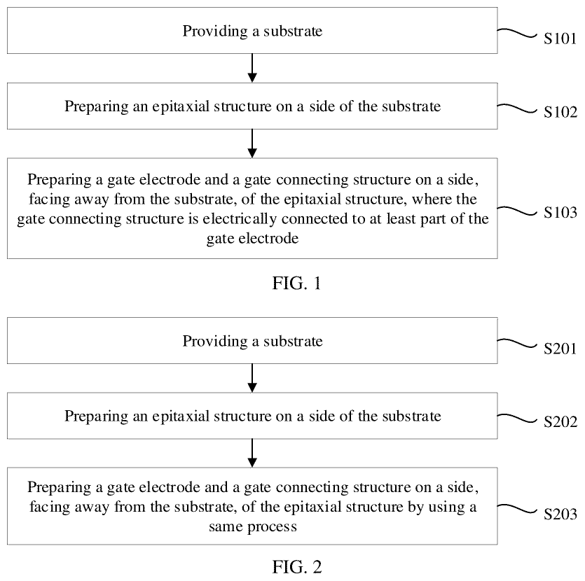

Optionally, FIG. 2 is a flowchart of a preparation method for a semiconductor device provided by another embodiment of the present disclosure. The preparation method shown in FIG. 2 provides specific instructions on how to prepare the gate electrode and gate connecting structure. As shown in FIG. 2, the preparation method for the semiconductor devices includes the following steps.

S201: providing a substrate.

S202: preparing an epitaxial structure on a side of the substrate.

S203: preparing a gate electrode and a gate connecting structure on a side, facing away from the substrate, of the epitaxial structure by using a same process.

Specifically, the gate connecting structure includes a first gate connecting section and a second gate connecting section interconnected with each other. In the thickness direction of the semiconductor device, an orthographic projection of the first gate connecting section does not overlap with an orthographic projection of the gate electrode, and the second gate connecting section is electrically connected to the gate electrode.

Exemplarily, the gate electrode and the gate connecting structure may be prepared by a same process. For example, the gate electrode and gate connecting structure may be prepared simultaneously by using a same mask process, thereby simplifying the preparation process of the gate electrode and the gate connecting structure. Meanwhile, by using the same process to prepare the gate electrode and the gate connecting structure, it may be ensured that the gate electrode and the gate connecting structure are arranged in a same layer, thereby simplifying a structure of the semiconductor device.

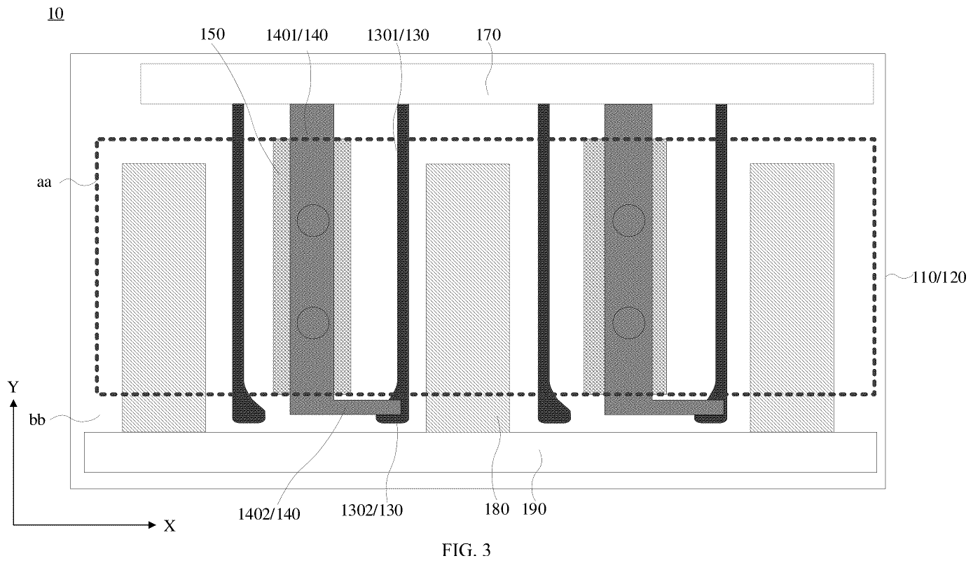

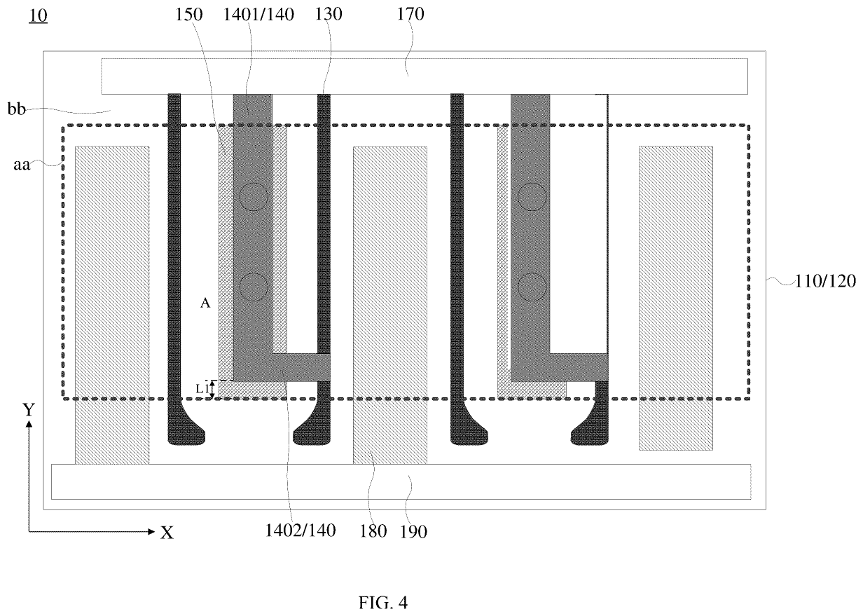

Furthermore, FIG. 3 is a schematic structural diagram of a semiconductor device provided by an embodiment of the present disclosure. FIG. 4 is a schematic structural diagram of a semiconductor device provided by another embodiment of the present disclosure. As shown in FIGS. 3 and 4, the gate connecting structure 140 includes a first gate connecting section 1401 and a second gate connecting section 1402 interconnected with each other. In a thickness direction of the semiconductor device, an orthographic projection of the first gate connecting section 1401 does not overlap with an orthographic projection of the gate electrode 130, and the second gate connecting section 1402 is electrically connected to the gate electrode 130. Specifically, the first gate connecting section 1401 has a relatively large area, serving as a main adjustment structure for gate gain, which may optimize an electric field of the gate electrode 130, reduce resistance of the gate electrode 130, and improve gain of the gate electrode 130. The second gate connecting section 1402 serves as a connection portion between the gate electrode 130 and the gate connecting structure 140, ensuring normal connection between the gate electrode 130 and the gate connecting structure 140, thereby reducing the resistance of the gate electrode 130. In the thickness direction of the semiconductor device 10, an orthographic projection of the gate electrode 130 does not overlap with an orthographic projection of the first gate connecting section 1401. In other words, in a second direction (a direction of X shown in FIGS. 3 and 4), the first gate section 1301 does not overlap with the first gate connecting section 1401, that is, the first gate section 1301 is staggered with the first gate connecting section 1401. Since charging and discharging speed of a junction capacitance may be affected by resistance of the gate electrode 130, which may further affect switching speed of the semiconductor device 10, the smaller the resistance of the gate electrode 130 is, the faster the switching speed of the semiconductor device 10 is. By electrically connecting the second gate connecting section 1402 in the gate connecting structure 140 to the gate electrode 130, the resistance of the gate electrode 130 may be reduced, thereby improving the switching speed of the semiconductor device 10.

On the basis of the above embodiment, further referring to FIG. 3, the semiconductor device 10 may include an active region aa and a passive region bb surrounding the active region aa. The gate electrode 130 includes a first gate section 1301 and a second gate section 1302 interconnected with each other. The second gate section 1302 is located in the passive region bb, and the second gate connecting section 1402 is located in the passive region bb. The second gate connecting section 1402 is electrically connected to the second gate section 1302.

Specifically, the active region aa can be understood as a region where a two-dimensional electron gas (2DEG), electrons, or holes exist below. An operating state and characteristics of the active region are influenced by external circuits, making it an active working region of the semiconductor device 10. The passive region bb participates in the operation of the semiconductor device 10, but its operating state is not affected by the external circuits. Exemplarily, lead-out structures for electrodes in the active region aa may be provided in the passive region bb, and the passive region bb may be arranged to surround the active region aa.

The gate electrode 130 includes the first gate section 1301 and the second gate section 1302 interconnected with each other, and the gate connecting structure 140 includes the first gate connecting section 1401 and the second gate connecting section 1402 interconnected with each other. The first gate section 1301 includes a part located in the active region aa that forms a Schottky contact with the epitaxial structure 120 and another part extending in the first direction Y to connect to a gate pad 170. The first gate section 1301 serves as a gate structure of the semiconductor device 10, controlling turn-on and turn-off of the gate electrode 130 and thus the operating state of the semiconductor device 10. The first gate connecting section 1401 is located in the active region aa and has a relatively large area, serving as a main adjustment structure for gate gain, reducing resistance of the gate electrode 130 and improving a gain of the gate electrode 130. The second gate section 1302 and the second gate connecting section 1402 are both located in the passive region bb and serve as connection portions between the gate electrode 130 and the gate connecting structure 140, ensuring normal connection between the gate electrode 130 and the gate connecting structure 140 and reducing resistance of the gate electrode 130. Further, the electrical connection between the second gate section 1302 and the second gate connecting section 1402 in the passive region bb does not affect an arrangement of the semiconductor device 10 in the active region aa and a normal operation and performance of the active region aa, thereby ensuring the stability of performance of the semiconductor device 10. Moreover, since the passive region bb offers more design space, the second gate section 1302 and the second gate connecting section 1402 can be designed with greater flexibility, enhancing connection stability between the second gate section 1302 and the second gate connecting section 1402.

On the basis of the above embodiment, further referring to FIG. 4, the semiconductor device 10 includes an active region aa and a passive region bb surrounding the active region aa. The second gate connecting section 1402 is located in the active region aa. In other words, the gate connecting structure 140 is electrically connected to the gate electrode 130 in the active region aa instead of the passive region bb. Thus, while ensuring reduction of resistance of the gate electrode 130, improvement of the switching speed, and enhancement of gain, the semiconductor device structure may be ensured to be compact, which is conducive to the miniaturization design of the semiconductor device.

The gate electrode 130 forms a Schottky contact with the epitaxial structure 120, while the gate connecting structure 140 does not form a Schottky contact with the epitaxial structure 120. Specifically, the gate connecting structure 140 is not in direct contact with a conductive channel (e.g., the 2DEG) in the epitaxial structure 120. The gate connecting structure 140 is connected to the gate electrode 130 through at least two channels, creating a parallel connection between the gate connecting structure 140 and the gate electrode 130. Optionally, the gate connecting structure 140 may be connected to the gate electrode 130 through the second gate connecting section 1402 and a gate pad 170 (as shown in FIG. 3). Optionally, the gate connecting structure 140 may be connected to the gate electrode 130 through at least two second gate connecting sections 1402 (not shown in figures). Exemplarily, the gate connecting structure 140 may be connected to the gate electrode 130 through two second gate connecting sections 1402, where one second gate connecting section 1402 is located in the active region aa and the other second gate connecting section 1402 is located in the passive region bb. Alternatively, both the second gate connecting sections are located in the active region aa.

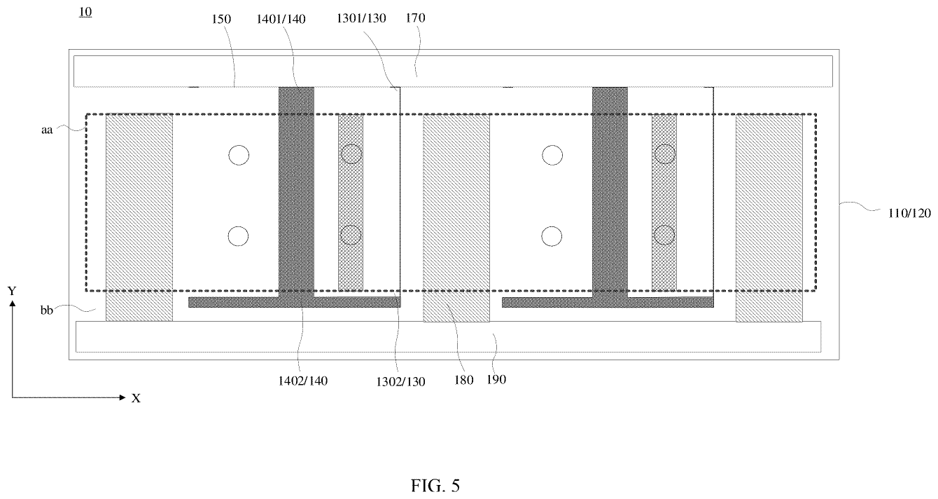

On the basis of the above embodiments, FIG. 5 is a schematic structural diagram of a semiconductor device provided by still another embodiment of the present disclosure. Combining FIGS. 3, 4, and 5, it can be seen that in the preparation method provided in the embodiments of the present disclosure, before the preparing the gate electrode and the gate connecting structure on the side, facing away from the substrate, of the epitaxial structure by using the same process, the method may further include: preparing a source electrode on the side, facing away from the substrate, of the epitaxial structure, where an ohmic structure is formed by the source electrode and the epitaxial structure.

Specifically, the source electrode may be connected to a backside of the semiconductor device through a source through-hole. Exemplarily, the source through-hole may penetrate the substrate and the epitaxial structure, that is, a source signal input electrode D on a side, facing away from the epitaxial structure, of the substrate (not shown in figures) is connected to the source electrode through the source through-hole. In other words, the source electrode is electrically connected to the source signal input electrode through the source via hole.

Further referring to FIGS. 3 and 4, in the thickness direction of semiconductor device 10, an orthographic projection of the first gate connecting section 1401 overlaps with an orthographic projection of the source electrode 150 and the first gate connecting section 1401 is insulated from the source electrode 150.

Exemplarily, further referring to FIGS. 3 and 4, the first gate connecting section 1401 may be located above the source electrode 150, so that the orthographic projection of the first gate connecting section 1401 overlaps with the orthographic projection of the source electrode 150. On one hand, this arrangement does not affect signal leading out of the gate electrode 130; on the other hand, an area of the semiconductor device 10 may be reduced by the overlap between the orthographic projection of the first gate connecting section 1401 and the orthographic projection of the source electrode 150. Further, the first gate connecting section 1401 may be positioned above the source via hole to ensure stability of a region of the source via hole, enabling normal operation of the semiconductor device 10.

Further referring to FIG. 5, in a second direction X, the first gate connecting section 1401 is located on a side, farther away from the gate electrode 130, of the source electrode 150.

Exemplarily, further referring to FIG. 5, as for a semiconductor device with a multi cell structure, in the second direction X, the first gate connecting section 1401 is located on the side, farther away from the gate electrode 130, of the source electrode 150 and between two adjacent source electrodes 150, with two adjacent transistor cells sharing the same first gate connecting section 1401. This arrangement changes a conventional layout where adjacent transistor cells share a single source electrode to a layout where a drain electrode 180, a gate electrode 130, a source electrode 150, a gate connecting structure 140, a source electrode 150, a gate electrode 130, a drain electrode 180 are arranged in sequence. In other words, adjacent transistor cells share one first gate connecting section 1401, while each cell retains its own source electrode 150, gate electrode 130, and drain electrode 180. Thus, an impact of resistance of the gate electrode may be reduced, gain is improved and leakage current is reduced.

Exemplarily, further referring to FIG. 5, in the second direction X, the first gate connecting section 1401 maintains a certain spacing from the adjacent source electrodes 150, with equal spacing between them.

FIG. 5 only illustrates a semiconductor device including a multi-cell structure. It can be understood that the semiconductor device can also include a single-cell structure. At this time, the first gate connecting section may also be located on the side, farther away from the gate electrode in the second direction X, of the source electrode, which will not be repeated here.

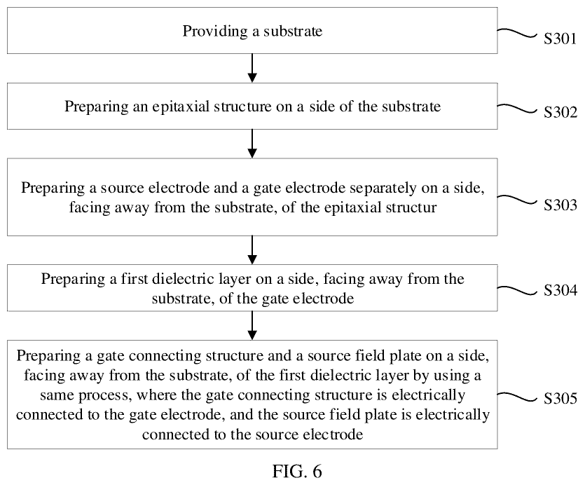

FIG. 6 is a schematic flowchart of a preparation method of a semiconductor device provided by still another embodiment of the present disclosure. The preparation method shown in FIG. 6 provides specific instructions on how to prepare the gate electrode and gate connecting structure. As shown in FIG. 6, the preparation method of semiconductor devices includes the following steps.

S301: providing a substrate.

S302: preparing an epitaxial structure on a side of the substrate.

S303: preparing a source electrode and a gate electrode separately on a side, facing away from the substrate, of the epitaxial structure.

S304: preparing a first dielectric layer on a side, facing away from the substrate, of the gate electrode.

S305: preparing a gate connecting structure and a source field plate on a side, facing away from the substrate, of the first dielectric layer by using a same process, where the gate connecting structure is electrically connected to the gate electrode, and the source field plate is electrically connected to the source electrode.

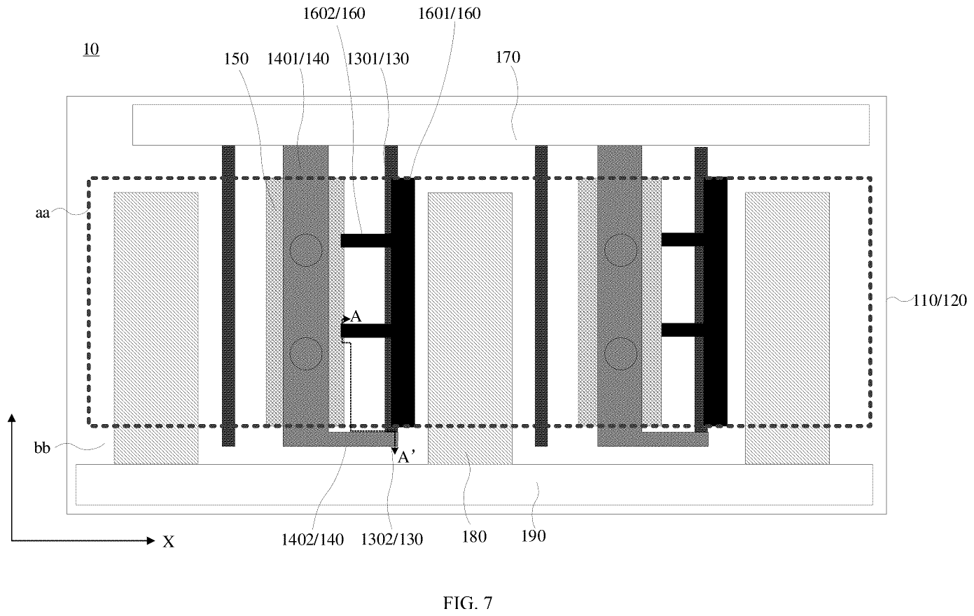

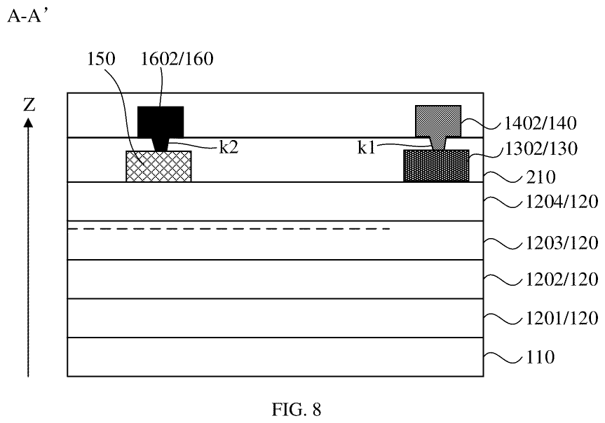

FIG. 7 is a schematic structural diagram of a semiconductor device provided in yet still another embodiment of the present disclosure, and FIG. 8 is a cross-sectional view of the semiconductor device provided in FIG. 7 along the section line A-A′. With reference to FIGS. 7 and 8, in the preparation method provided by the embodiment of the present disclosure, a source electrode 150 and a drain electrode 180 are prepared on a side, facing away from the substrate 110, of the epitaxial structure 120, and both the source electrode 150 and the drain electrode 180 form an ohmic structure with the epitaxial structure 120. Afterwards, a gate electrode 130 is prepared on the side, facing away from the substrate 110, of the epitaxial structure 120, and between the source electrode 150 and the drain electrode 180. The gate electrode 130 located in the active region aa forms a Schottky structure with the epitaxial structure 120.

Secondly, a first dielectric layer 210 is prepared on the side, away from the substrate 110, of the source electrode 150 and the gate electrode 130. The first dielectric layer 210 covers the source electrode 150 and the gate electrode 130. A same mask process may be used to prepare the first connection via hole K1 and the second connection via hole K2 in the first dielectric layer 210. The first connection via hole K1 exposes a portion of the gate electrode 130, and the second connection via hole K2 exposes a portion of the source electrode 150. Exemplarily, the first dielectric layer 210 may be made of materials such as silicon dioxide, silicon nitride, and aluminum oxide. A preparation method of the first dielectric layer 210 includes physical vapor deposition and/or chemical vapor deposition. The first dielectric layer 210 may cover the structure of the electrodes.

Thirdly, a gate connecting structure 140 and a source field plate 160 are prepared by using a same process on a side, facing away from the substrate 110, of the first dielectric layer 210. The gate connecting structure 140 is electrically connected to the gate electrode 130 through the first connection via hole K1, and the source field plate 160 is electrically connected to the source electrode 150 through the second connection via hole K2.

The first connection via hole K1 exposes a portion of the gate electrode 130, and the gate connecting structure 140 may be grown continuously in an exposed area of the gate electrode 130. The gate connecting structure 140 is electrically connected to the gate electrode 130 through the first connection via hole K1, which can reduce the resistance of the gate electrode 130, improve the gain, and improve the stability of the connection, thereby ensuring the performance of the semiconductor device. Furthermore, the second connection via hole K2 exposes a portion of the source electrode 150, allowing for continued growth of the source field plate 160 in an exposed area of the source electrode 150. The source field plate 160 is electrically connected to the source electrode 150 through the second connection via hole K2, which can reduce the resistance of the source electrode 150 and improve the stability of the connection, thereby ensuring the performance of the semiconductor device. Moreover, the gate connecting structure 140 is arranged in a same layer as the source field plate 160 and prepared in the same process, thereby simplifying the manufacturing process, avoiding requirement for additional film layers, simplifying a mask process, and facilitating lightweight design of semiconductor devices.

The first dielectric layer in the embodiments of the present disclosure maybe referred to a single-layer dielectric layer or a multi-layer dielectric layer, which is not limited in the embodiments of the present disclosure.

In view of above, the preparation method provided in the embodiments of the present disclosure may simplify the manufacturing process by using the same material to prepare the gate connecting structure and the source field plate in the same process. On one hand, it can be avoided to set additional film layers, thereby simplifying the mask process; on the other hand, it is conducive to achieving lightweight design of semiconductor devices.

Furthermore, further referring to FIG. 8, a thickness of the gate connecting structure 140 is greater than a thickness the first dielectric layer 210, and a thickness of the source field plate 160 is greater than the thickness of the first dielectric layer 210, which can reduce gate parasitic capacitance and ensure the performance of the semiconductor device.

Furthermore, further referring to FIGS. 7 and 8, the semiconductor device 10 includes an active region aa and a passive region bb surrounding the active region aa; The source field plate 160 includes a field plate body 1601 and a field plate connecting portion 1602. The field plate connecting portion 1602 is electrically connected to the source electrode 150 through the second connection via hole K2; The gate connecting structure 140 includes a first gate connecting section 1401 and a second gate connecting section 1402 interconnected with each other. The second gate connecting section 1402 is electrically connected to the gate electrode 130 through the first connection via hole K1. The field board connecting portion 1602 is staggered with the first connection via hole K1, and the second gate connecting section 1402 is staggered with the second connection via hole K2.

Specifically, the field plate connecting portion 1602 is electrically connected to the source electrode 150 through the second connection via hole K2, to achieve electrical connection between the source field plate 160 and the source electrode 150. Furthermore, the field plate connecting portion 1602 is staggered with the first connection via hole K1, that is, an orthographic projection of the field plate connecting portion 1602 does not overlap with n orthographic projection of the first connection via hole K1, which may avoid overlapping between the field plate connecting portion 1602 and the gate connecting structure 140, thus avoiding mutual interference. In addition, the second gate connecting section 1402 is staggered with the second connection via hole K2, which can avoid mutual interference between the source field plate 160 and the second gate connecting section 1402 of the gate connecting structure 140, thereby ensuring the operational performance of the semiconductor device 10.

FIG. 7 only illustrates a case where the second gate connecting section 1402 is located in the passive region as an example. The second gate connecting section 1402 may be located in the active region aa or in the passive region bb. Regardless of whether the second gate connecting section 1402 is located in the active region aa or the passive region bb, it is staggered the second connection via hole K2 to avoid mutual interference between the source field plate 160 and the gate connecting structure 140.

Optionally, further referring to FIG. 7, the semiconductor device 10 includes an active region aa and a passive region bb surrounding the active region aa.

The gate connecting structure 140 includes a first gate connecting section 1401 and a second gate connecting section 1402 interconnected with each other. The second gate connecting section 1402 is electrically connected to the gate electrode 130 through a first connection via hole K1.

The second gate connecting section 1402 is located in the passive region bb. The total area of an opening of the second connecting via K2 is S1, and an area of the source electrode is S2. Therein, S1/S2≥50%.

Specifically, the source field plate 160 is electrically connected to the source electrode 150 through the second connection via hole K2. As for the total area SI of the opening of the second connection via hole K2 and the area S2 of the source electrode 150, it is satisfied that S1/S2≥50%, which means that the total area of the opening of the second connection via hole K2 is greater than half of the area of the source electrode 150, so that a large area of the source electrode 150 may be exposed in the first dielectric layer 210, allowing exposed metal of the source electrode to be electrically connected to the source field plate 160 over a large area through the second connection via hole K2. Thus, on one hand, the function of the source field plate may be achieved; on the other hand, the connection stability may be ensured.

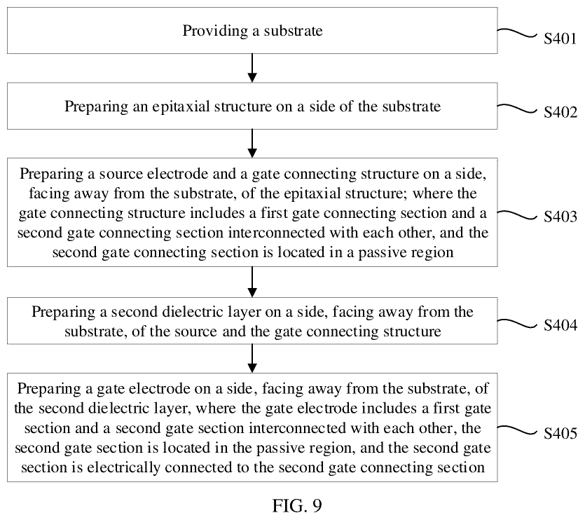

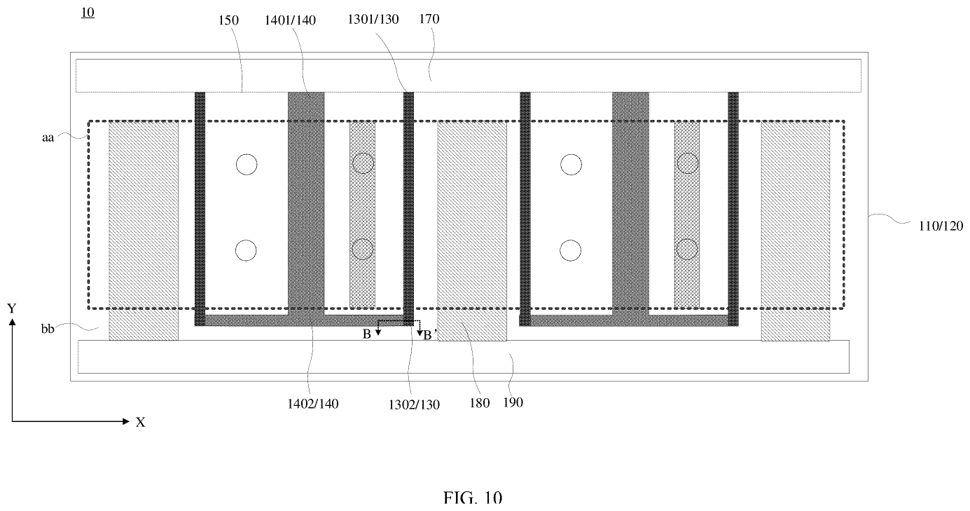

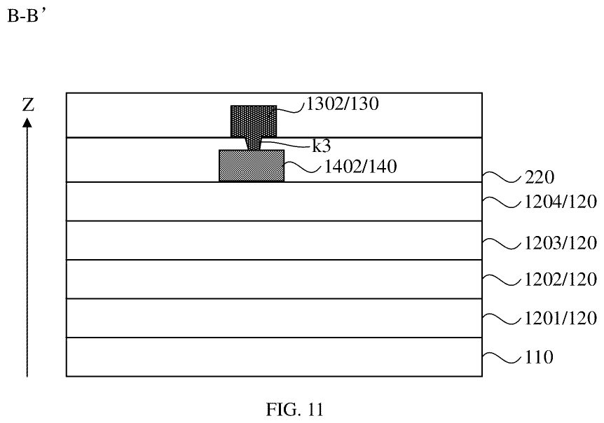

FIG. 9 is a flowchart of the preparation method of a semiconductor device provided be yet still another embodiment of the present disclosure, FIG. 10 is a schematic structural diagram of the semiconductor device provided by yet still another embodiment of the present disclosure, and FIG. 11 is a cross-sectional view of the semiconductor device provided in FIG. 10 in the section line B-B′. With reference to FIGS. 9, 10, and 11, the preparation method of the semiconductor device provided in the embodiments of the present disclosure includes: the following steps.

S401: providing a substrate.

S402: preparing an epitaxial structure on a side of the substrate.

S403: preparing a source electrode and a gate connecting structure on a side, facing away from the substrate, of the epitaxial structure; where the gate connecting structure includes a first gate connecting section and a second gate connecting section interconnected with each other, and the second gate connecting section is located in a passive region.

Exemplarily, the gate connecting structure 140 and the source electrode 150 are arranged in a same layer and prepared in a same process. Thus, on one hand, the manufacturing process is simplified and requirement for additional film layers is avoided to simplify the mask process; on the other hand, it is conducive to realize the lightweight design of semiconductor devices.

Moreover, the gate connecting structure 140 includes the first gate connecting section 1401 and the second gate connecting section 1402 interconnected with each other. As the gate connecting structure 140 needs to be electrically connected to the gate electrode 130, the second gate connecting section 1402 may be set in the passive region bb. Thus, an electrical connection between the second gate connecting section 1402 and the gate electrode 130 may not cause a short circuit between the gate connecting structure 140 and the source electrode 150.

S404: preparing a second dielectric layer on a side, facing away from the substrate, of the source and the gate connecting structure.

Exemplarily, the second dielectric layer 220 is prepared on the side, facing away from the substrate 110, of the source electrode 150 and the gate connecting structure 140, and the second dielectric layer 220 may cover the source electrode 150 and the gate connecting structure 140. Moreover, a third connection via hole K3 may be further prepared in the second dielectric layer 220 to exposes a portion of the second gate connecting section 1402, facilitating subsequent electrical connection between the gate electrode 130 and the second gate connecting section 1402 through the third connection via hole K3.

Furthermore, the second dielectric layer 220 may be made of materials such as silicon dioxide, silicon nitride, and aluminum oxide. A preparation method of the second dielectric layer 220 includes physical vapor deposition and/or chemical vapor deposition.

S405: preparing a gate electrode on a side, facing away from the substrate, of the second dielectric layer, where the gate electrode includes a first gate section and a second gate section interconnected with each other, the second gate section is located in the passive region, and the second gate section is electrically connected to the second gate connecting section.

Specifically, the gate electrode 130 includes the first gate section 1301 and the second gate section 1302 interconnected with each other. The second gate section 1302 is electrically connected to the second gate connecting section 1402 through the third connection via hole K3, thereby achieving electrical connection between the gate electrode 130 and the gate connecting structure 140, reducing impedance of the gate electrode 130, and improving the performance of the semiconductor device.

The second dielectric layer in the embodiments of the present disclosure may be referred to a single-layer dielectric layer or a multi-layer dielectric layer, which is not limited in the embodiments of the present disclosure.

In view of above, according to the preparation method provided by the embodiments of the present disclosure, a manufacturing process is simplified by using the same process to prepare the source electrode and the gate connecting structure on the side, facing away from the substrate, of the epitaxial structure. On one hand, it may be avoided to set additional film layers, thereby simplifying the mask process; on the other hand, it is conducive to achieving lightweight design of semiconductor devices.

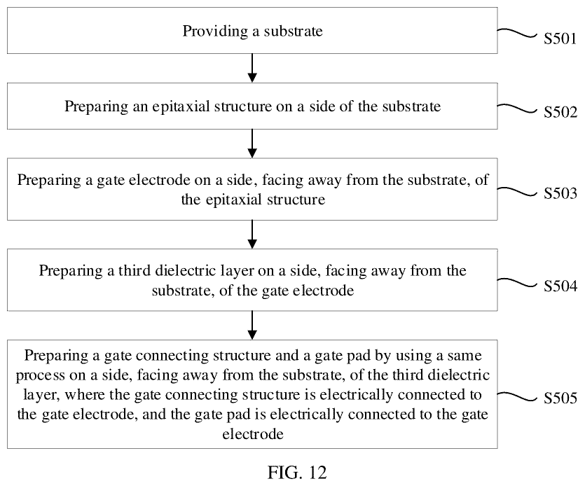

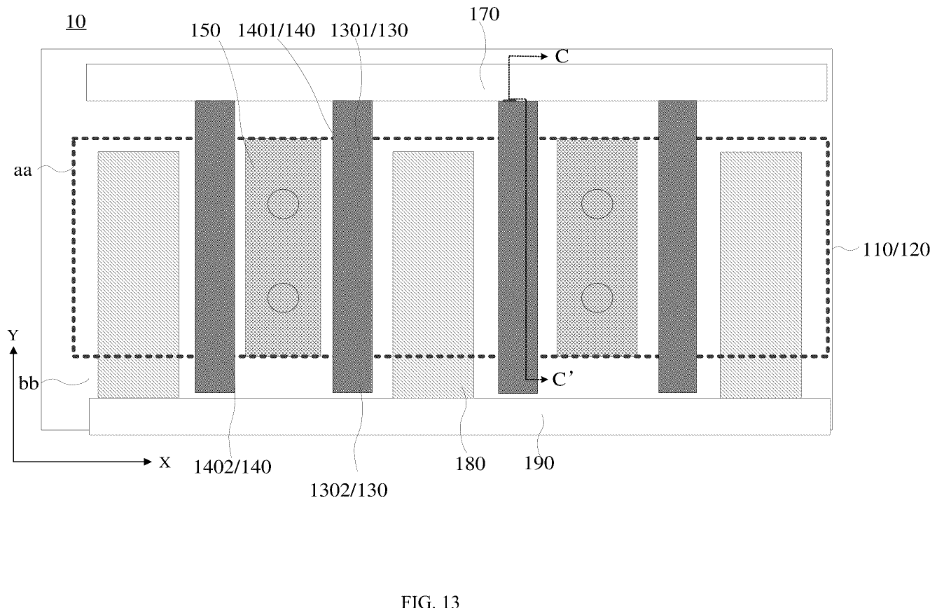

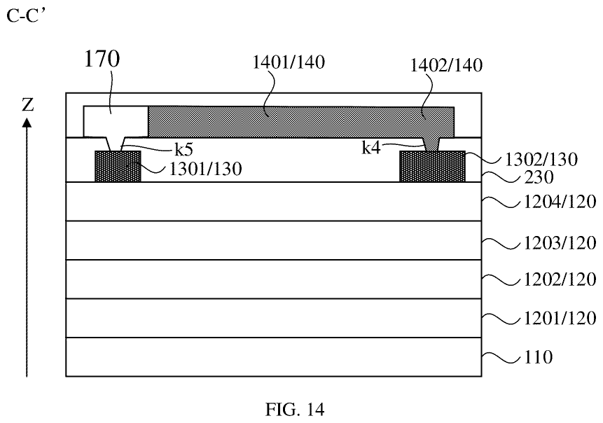

FIG. 12 is a flowchart of a preparation method for a semiconductor device provided by yet still another embodiment of the present disclosure, FIG. 13 is a schematic structural diagram of the semiconductor device provided by yet still another embodiment of the present disclosure, and FIG. 14 is a cross-sectional view of the semiconductor device provided in FIG. 13 in the section line C-C′. With reference to FIGS. 12 to 14, the preparation method provided in the embodiments of the present disclosure includes the following steps.

S501: providing a substrate.

S502: preparing an epitaxial structure on a side of the substrate.

S503: preparing a gate electrode on a side, facing away from the substrate, of the epitaxial structure.

S504: preparing a third dielectric layer on a side, facing away from the substrate, of the gate electrode.

Exemplarily, the third dielectric layer 230 is prepared on the side, facing away from the substrate 110, of the gate electrode 130, and the third dielectric layer 230 may cover the gate electrode 130. A fourth connection via hole K4 and a fifth connection via hole K5 may be further prepared in the third dielectric layer 230. Both the fourth connection via hole K4 and the fifth connection via hole K5 expose a portion of the gate electrode 130, facilitating an electrical connection between the gate connecting structure 140 and the gate pad 170 through the fourth connection via hole K4 and an electrical connection between the gate connecting structure 140 and the gate electrode 130 through the fifth connection via hole K5.

Furthermore, the third dielectric layer 230 may be made of materials such as silicon dioxide, silicon nitride, and aluminum oxide. A preparation method of the third dielectric layer 230 may include physical vapor deposition and/or chemical vapor deposition.

S505: preparing a gate connecting structure and a gate pad by using a same process on a side, facing away from the substrate, of the third dielectric layer, where the gate connecting structure is electrically connected to the gate electrode, and the gate pad is electrically connected to the gate electrode.

Exemplarily, the gate connecting structure 140 and the gate pad 170 may be provided in the same layer and prepared in the same process. On one hand, it may be avoided to set additional film layers, thereby simplifying the mask process; on the other hand, it is conducive to achieving lightweight design of semiconductor devices.

When the gate connecting structure and the gate pad are provided in the same layer and prepared in the same process, the gate connecting structure and the gate electrode may be connected in the passive region or in the active region, which is not limited in embodiments of the present disclosure. FIG. 13 only illustrates a case where the gate connecting structure 140 is electrically connected to the gate electrode 130 in the passive region bb as an example. At this time, the gate electrode 130 includes a first gate section 1301 and a second gate section 1302 interconnected with each other, with the second gate section 1302 located in the passive region bb. Correspondingly, the gate connecting structure 140 includes a first gate connecting section 1401 and a second gate connecting section 1402 interconnected with each other. The second gate connecting section 1402 is located in the passive region bb, and is electrically connected to the second gate section 1302 through the fourth connection via hole K4 in the passive region bb.

The gate connecting structure and the gate pad are provided in the same layer and prepared in the same process, so that a material of the gate connecting structure may be the same as a material of the gate pad. In order to distinguish between the gate connecting structure and the gate pad in FIG. 13, different fillers are used for illustrating the gate connecting structure and the gate pad, which is only used for distinguishing different results, not for limiting the materials.

The third dielectric layer in the embodiments of the present disclosure may be referred to a single-layer dielectric layer or a multi-layer dielectric layer, which is not limited in the embodiments of the present disclosure.

In view of above, according to the preparation method provided by the embodiments of the present disclosure, a manufacturing process is simplified by using the same process to prepare the gate connecting structure and the gate pad on the side, facing away from the substrate, of the epitaxial structure. On one hand, it may be avoided to set additional film layers, thereby simplifying the mask process; on the other hand, it is conducive to achieving lightweight design of semiconductor devices

Further referring to FIGS. 13 and 14, the semiconductor device 10 includes an active region aa and a passive region bb surrounding the active region aa; A fourth connection via hole K4 and a fifth connection via hole K5 are respectively located in two passive regions bb on opposite sides of the active region aa to ensure a simple connection relationship between the gate electrode 130 and the gate pad 170 as well as between the gate electrode 130 and the gate connecting structure 140, thereby avoiding complexity of a preparation process of via holes when connections are provided at a same side.

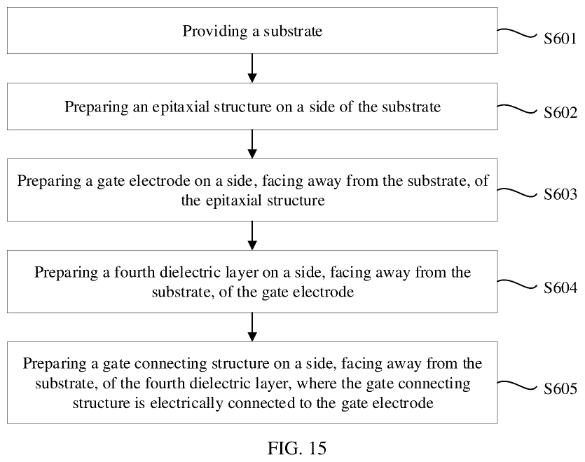

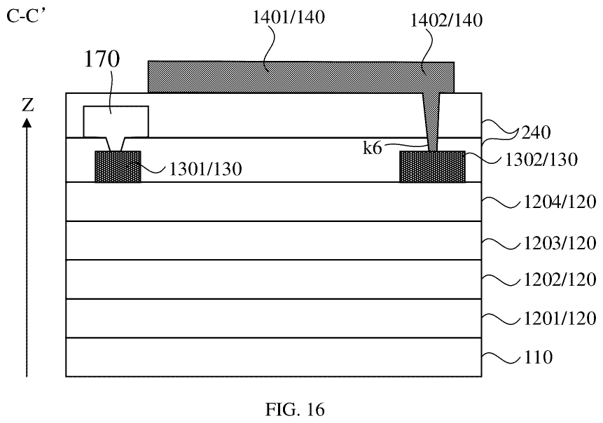

FIG. 15 is a flowchart of yet still another preparation method for a semiconductor device provided by an embodiment of the present disclosure, and FIG. 16 is a cross-sectional view of the semiconductor device provided in FIG. 13 in the section line C-C′. With reference to FIGS. 15 and 16, the preparation method provided in the present embodiment includes the following steps.

S601: providing a substrate.

S602: preparing an epitaxial structure on a side of the substrate.

S603: preparing a gate electrode on a side, facing away from the substrate, of the epitaxial structure.

S604: preparing a fourth dielectric layer on a side, facing away from the substrate, of the gate electrode.

Exemplarily, the fourth dielectric layer 240 is prepared on the side, facing away from the substrate 110, of the gate electrode 130. The fourth dielectric layer 240 may cover the gate electrode 130. A sixth connection via hole K6 can be further prepared in the fourth dielectric layer 240 to expose a portion of the gate electrode 130, thereby facilitating subsequent electrical connection between the gate connecting structure 140 and the gate electrode 130 through the sixth connection via hole K6.

Furthermore, the fourth dielectric layer 240 may be made of materials such as silicon dioxide, silicon nitride, and aluminum oxide. A preparation method of the fourth dielectric layer 240 may include physical vapor deposition and/or chemical vapor deposition.

S605: preparing a gate connecting structure on a side, facing away from the substrate, of the fourth dielectric layer, where the gate connecting structure is electrically connected to the gate electrode.

Exemplarily, the gate connecting structure 140 is prepared on the side, facing away from the substrate 110, of the fourth dielectric layer 240. The gate connecting structure 140 is electrically connected to the gate electrode 130 through a sixth connection via hole K6, thereby reducing resistance of the gate electrode, reducing leakage, and improving the performance of the semiconductor device.

The fourth dielectric layer in the embodiments of the present disclosure may be referred to a single-layer dielectric layer or a multi-layer dielectric layer, which is not limited in the embodiments of the present disclosure.

In view of above, according to the preparation method provided by the embodiments of the present disclosure, the gate connecting structure may be independently prepared, so that film and process limitations of the gate connecting structure may be alleviated, thereby improving preparation freedom of the gate connecting structure, reducing preparation difficulty of the gate connecting structure, and improving preparation efficiency.

On the basis of the above embodiments, further referring to FIG. 13, in a thickness direction of the semiconductor device, an orthographic projection of the gate electrode 130 at least partially overlaps with an orthographic projection of the gate connecting structure 140, so that an area of the semiconductor device in the second direction X may be reduced, thereby achieving miniaturization design of the semiconductor device.

Further referring to FIGS. 3, 4, 5, 7, 10, and 13, the preparation method provided in the embodiments of the present disclosure may further include: preparing a drain electrode 180 and a drain pad 190, where the drain electrode 180 is electrically connected to the drain pad 190 in the passive region bb. A drain signal may be applied to the drain electrode 180 through the drain pad 190. Furthermore, the drain electrode 180 may be prepared in the same process as the source electrode 150 and arranged in the same layer as the source electrode 150. The drain pad 190 may also prepared in the same process as the gate pad 170 and arranged in the same layer as the gate pad 170, thereby ensuring a simple preparation process of semiconductor device and simple arrangement of film layers.

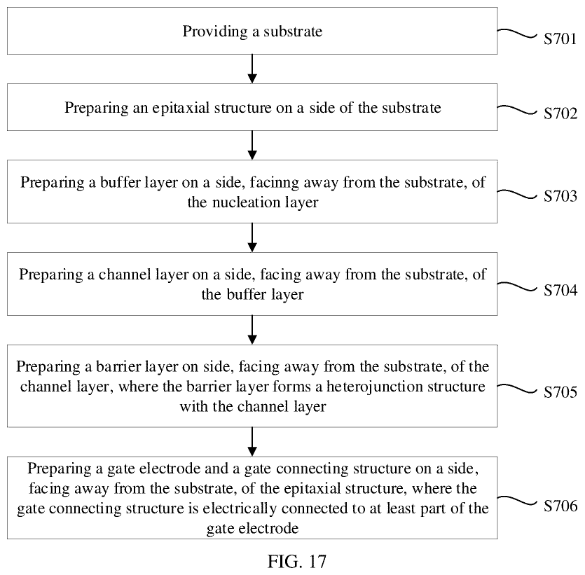

Optionally, FIG. 17 is a flowchart of yet still another preparation method for a semiconductor device provided by an embodiment of the present disclosure. As shown in FIG. 17, the preparation method of semiconductor devices includes the following steps.

S701: providing a substrate.

S702: preparing a nucleation layer on a side of the substrate.

Exemplarily, referring to FIGS. 8, 11, 14, and 16, a material of the nucleation layer 1201 may be aluminum nitride. The nucleation layer 120 is located between substrate 110 and buffer layer 1202, which is configured to bond semiconductor material layers that needs to be grown next.

S1003: preparing a buffer layer on a side, facing away from the substrate, of the nucleation layer.

Exemplarily, referring to FIGS. 8, 11, 14, and 16, the buffer layer 1202 is located on the side facing away from the substrate110, of the nucleation layer. The material of the buffer layer 1202 may be gallium nitride, and iron atoms can be included in the buffer layer 1202, which is beneficial for achieving high resistance performance of the buffer layer 1202, thereby ensuring blocking of vertical leakage, and improving pinch off performance of the semiconductor device.

S704: preparing a channel layer on a side, facing away from the substrate, of the buffer layer.

Exemplarily, further referring to FIGS. 8, 11, 14, and 16, a material of the channel layer 1203 may be a Group III nitride material, such as AlₓGa₁₋ₓN, where 0≤x<1. That is, at the interface between the channel layer 1203 and the barrier layer 1204, energy at an edge of a conduction band of the channel layer 1203 is less than energy at an edge of the conduction band edge of the barrier layer 1204. Exemplarily, x=0, which indicates that the material of the channel layer 1203 is GaN. The material of the channel layer 1203 may also be other group III nitrides material, such as InGaN and AlInGaN. The channel layer 1203 can be undoped or unintentionally doped. The channel layer 1203 may also be a multi-layer structure, such as a combination of superlattice, GaN, and AlGaN.

S705: preparing a barrier layer on side, facing away from the substrate, of the channel layer, where the barrier layer forms a heterojunction structure with the channel layer.

Exemplarily, referring to FIGS. 8, 11, 14, and 16, a material of the barrier layer 1204 may be AlN, AlInN, AlGaN, or AlInGaN. The barrier layer 1204 has sufficient thickness and a high composition of Al, so that a carrier concentration at the interface doped between the channel layer 1203 and the barrier layer 1204 is high enough. Exemplarily, the thickness of the barrier layer 1204 may be 20 nm, and a doping concentration of the Al component may be 25%.

Exemplarily, further referring to FIGS. 8, 11, 14, and 16, a material of the channel layer 1203 may include GaN, while the material of the barrier layer 1204 may include AlGaN, that is, the material of the barrier layer 1204 has a higher band gap than that of the channel layer 1203, and the channel layer 1204 may also have a greater electron affinity than the barrier layer 1204. Due to the band gap difference between the barrier layer 1204 and the channel layer 1203, as well as a piezoelectric effect at the interface between the barrier layer 1204 and the channel layer 1203, a two-dimensional electron gas (2DEG) may be formed between the channel layer 1203 and the barrier layer 1204.

The epitaxial structure may also include a cap layer, which is located on a surface, facing away from the substrate, of the barrier layer. The cap layer may reduce surface states, decrease surface leakage of subsequent semiconductor devices, suppress current collapse, thereby improving the performance and reliability of the epitaxial structure and the semiconductor device.

S706: preparing a gate electrode and a gate connecting structure on a side, facing away from the substrate, of the epitaxial structure, where the gate connecting structure is electrically connected to at least part of the gate electrode.

According to the preparation method of the semiconductor device provided by the embodiments of the present disclosure, a complete preparation of the epitaxial structure of the semiconductor device may be ensured by sequentially preparing a nucleation layer, a buffer layer, a channel layer, and a barrier layer on a side of the substrate.; Furthermore, by preparing the gate connecting structure on the side, facing away from the substrate, of the gate electrode, the gate connecting structure may be electrically connected to at least part of the gate electrode, which reduces influence of the resistance of the gate electrode and improves gain, thereby maintaining an optimized gate electric field and reducing leakage.

It should be noted that the above are only preferred embodiments and technical principles applied in the present disclosure. Those skilled in the art will understand that the present disclosure is not limited to the specific embodiments described herein, and various obvious modifications, readjustments, and substitutions may be made for those skilled in the art without departing from the scope of protection of the present disclosure. Therefore, although the present disclosure has been described in detail through the above embodiments, the present disclosure is not limited to the above embodiments, and may also include more equivalent embodiments without departing from the concept of the present disclosure. The scope of the present disclosure is determined by the scope of the appended claims.

What is claimed is:

1. A preparation method for a semiconductor device, comprising:
providing substrate;
preparing an epitaxial structure on a side of the substrate; and
preparing a gate electrode and a gate connecting structure on a side, facing away from the substrate, of the epitaxial structure, wherein the gate connecting structure is electrically connected to at least part of the gate electrode.

2. The method according to claim 1, wherein the preparing the gate electrode and the gate connecting structure on the side, facing away from the substrate, of the epitaxial structure comprises:
preparing the gate electrode and the gate connecting structure on the side, facing away from the substrate, of the epitaxial structure by a same process, wherein the gate connecting structure comprises a first gate connecting section and a second gate connecting section interconnected with each other, in a thickness direction of the semiconductor device, an orthographic projection of the first gate connecting section does not overlap with an orthographic projection of the gate electrode, and the second gate connecting section is electrically connected to the gate electrode.

3. The method according to claim 2, before the preparing the gate electrode and the gate connecting structure on the side, facing away from the substrate, of the epitaxial structure, further comprising:
preparing a source electrode on the side, facing away from the substrate, of the epitaxial structure; wherein
in the thickness direction of the semiconductor device, an orthographic projection of the first gate connecting section overlaps with an orthographic projection of the source electrode and the first gate connecting section is insulated from source electrode.

4. The method according to claim 2, before the preparing the gate electrode and the gate connecting structure on the side, facing away from the substrate, of the epitaxial structure, further comprising:
preparing a source electrode on the side, facing away from the substrate, of the epitaxial structure; wherein
in a second direction, the first gate connecting section is located on a side, farther away from the gate electrode, of the source electrode.

5. The method according to claim 2, wherein the semiconductor device comprises an active region and a passive region surrounding the active region; and
the second gate connecting section is located in the active region.

6. The method according to claim 2, wherein the semiconductor device comprises an active region and a passive region surrounding the active region; and
the gate electrode comprises a first gate section and a second gate section interconnected with each other, the second gate section is located in the passive region, the second gate connecting section is located in the passive region, and the second gate connecting section is electrically connected to the second gate section.

7. The method according to claim 1, wherein the preparing the gate electrode and the gate connecting structure on the side, facing away from the substrate, of the epitaxial structure comprises:
preparing a source electrode and a gate electrode on the side, facing away from the substrate, of the epitaxial structure, respectively;
preparing a first dielectric layer on a side, facing away from the substrate, of the gate electrode; and
preparing a gate connecting structure and a source field plate on a side, facing away from the substrate, of the first dielectric layer by using a same process, wherein the gate connecting structure is electrically connected to the gate electrode, and the source field plate is electrically connected to the source electrode.

8. The method according to claim 7, after the preparing the first dielectric layer on the side, facing away from the substrate, of the gate electrode, further comprising:
preparing a first connection via hole and a second connection via hole in the first dielectric layer by using a same process, wherein
the first connection via hole exposes the gate electrode and the second connection via hole exposes the source electrode, the gate connecting structure is electrically connected to the gate electrode through the first connection via hole, and the source field plate is electrically connected to the source electrode through the second connection via hole.

9. The method according to claim 8, wherein the source field plate comprises a field plate body and a field plate connecting portion, and the field plate connecting portion is electrically connected to the source electrode through the second connection via hole;
the gate connecting structure comprises a first gate connecting section and a second gate connecting section interconnected with each other, the second gate connecting section is electrically connected to the gate electrode through the first connection via hole; and
the field plate connecting portion is staggered with the first connection via hole; the second gate connecting section is staggered with the second connection via hole.

10. The method according to claim 7, wherein a thickness of the gate connecting structure is greater than a thickness of the first dielectric layer; and
a thickness of the source field plate is greater than the thickness of the first dielectric layer.

11. The method according to claim 7, wherein the semiconductor device comprises an active region and a passive region surrounding the active region;
the source field plate comprises a field plate body and a field plate connecting portion interconnected with each other, and the field plate connecting portion is electrically connected to the source electrode; and
the gate connecting structure comprises a first gate connecting section and a second gate connecting section interconnected with each other, and the second gate connecting section is electrically connected to the gate electrode.

12. The method according to claim 1, wherein the semiconductor device comprises an active region and a passive region surrounding the active region;
the preparing the gate electrode and the gate connecting structure on the side, facing away from the substrate, of the epitaxial structure comprises:
preparing a source electrode and the gate connecting structure on the side, facing away from the substrate, of the epitaxial structure by a same process, wherein the gate connecting structure comprises a first gate connecting section and a second gate connecting section interconnected with each other, and the second gate connecting section is located in the passive region;
preparing a second dielectric layer on a side, facing away from the substrate, of the source electrode and gate connecting structure; and
preparing the gate electrode on a side, facing away from the substrate, of the second dielectric layer, wherein the gate electrode comprises a first gate section and a second gate section interconnected to each other, the second gate section is located in the passive region; and the second gate section is electrically connected to the second gate connecting section.

13. The method according to claim 1, wherein the preparing the gate electrode and the gate connecting structure on the side, facing away from the substrate, of the epitaxial structure comprises:
preparing the gate electrode on the side, facing away from the substrate, of the epitaxial structure;
preparing a third dielectric layer on a side, facing away from the substrate, of the gate electrode;
preparing the gate connecting structure and a gate pad on a side, facing away from the substrate, of the third dielectric layer by using a same process, wherein the gate connecting structure is electrically connected to the gate electrode, and the gate pad is electrically connected to the gate electrode.

14. The method according to claim 13, after the preparing the third dielectric layer on the side, facing away from the substrate, of the gate electrode, further comprising:
preparing a fourth connection via hole and a fifth connection via hole in the third dielectric layer, wherein both the fourth connection via hole and the fifth connection via hole expose a portion of the gate electrode, the gate connecting structure is electrically connected to the gate electrode through the fourth connection via hole, and the gate pad is electrically connected to the gate electrode through the fifth connection via hole.

15. The method according to claim 1, wherein the preparing the gate electrode and the gate connecting structure on the side, facing away from the substrate, of the epitaxial structure comprises:
preparing the gate electrode on the side, facing away from the substrate, of the epitaxial structure;
preparing a fourth dielectric layer on a side, facing away from the substrate, of the gate electrode; and
preparing the gate connecting structure on a side, facing away from the substrate, of the fourth dielectric layer, wherein the gate connecting structure is electrically connected to the gate electrode.

16. The method according to claim 15, after the preparing the fourth dielectric layer on the side, facing away from the substrate, of the gate electrode, further comprising:
preparing a sixth connection via hole in the fourth dielectric layer, wherein the sixth connection via hole exposes a portion of the gate electrode, and the gate connecting structure is electrically connected to the gate electrode through the sixth connection via hole.

17. The method according to claim 15, wherein an orthographic projection of the gate electrode at least partially overlaps with an orthographic projection of the gate connecting structure in a thickness direction of the semiconductor device.
